(19) United States
(12) Patent Application Publication
(10) Pub. No.: US 2006/0076558 A1
(43) Pub. Date: Apr. 13, 2006

(54) Semiconductor device and manufacturing method thereof

(75) Inventors: Kiyoyuki Morita, Jouetsu-shi (JP); Hiroyuki Kamada, Jouetsu-shi (JP); Keita Uchiyama, Jouetsu-shi (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD, Osaka (JP)

(21) Appl. No.: 11/217,394

(22) Filed: Sep. 2, 2005

(30) Foreign Application Priority Data
Sep. 28, 2004 (JP) 2004-281854

(51) Int. Cl. H01L 21/66; H01L 23/58

(52) U.S. Cl. 257/48; 438/15; 438/18; 257/506; 438/207

(57) ABSTRACT

An object of the present invention is to prevent a junction leakage current generation across a pn junction formed under a silicide layer, even when a direct probing to an electrode formed of the silicide layer is performed. There is provided a semiconductor device including an element for evaluation, wherein the element for evaluation includes a device isolation region, a first diffusion layer region formed adjacent to the device isolation region, an electrode for probe formed to be electrically connected to the first diffusion layer region, a semiconductor region which is formed so as to contact to the first diffusion layer region, and has a conductivity type different from that of the first diffusion layer region, and an evaluation pattern which is formed to be electrically connected to the electrode for probe, and includes at least a part of the first diffusion layer region, and wherein a second diffusion layer region which has the same conductivity type as that of the first diffusion layer region is selectively formed under the first diffusion layer region formed under the electrode for probe to be contacted to the first diffusion layer region and the semiconductor region.

### BACKGROUND OF THE INVENTION

1. Field of the Invention

The present invention relates generally to a semiconductor device for managing a semiconductor manufacturing process and a manufacturing method thereof, and more particularly to a semiconductor device provided with an evaluation element for electrically evaluating a disconnection or a short circuit using a pattern for evaluation a defect density, and a manufacturing method thereof.

2. Description of the Prior Art

In a process of manufacturing a semiconductor device, a defect generated during the manufacturing process adversely affects a product yield of the semiconductor device greatly. Therefore, various techniques for managing the defect have conventionally been proposed and used. In order to extract with high sensitivity a killer defect that adversely affects the yield, an electrical detection method is suitable. It therefore becomes important to form a defect density evaluation element for detecting the defect with an electrical measurement to thereby manage the manufacturing process using the electrical evaluation.

A prototype for the defect density evaluation element is generally fabricated so that it may be completed with as few process stops as possible using a manufacturing process to which the defective management is to be performed as a target. Referring to FIG. 12, a conventional defect density evaluation element will be explained. Here, a defect density evaluation element in a device isolation forming process will be explained. The defect density evaluation element used as the evaluation element is composed of a main pattern portion for detecting a defect, and an electrode portion for measurement.

FIG. 12A is a plane schematic diagram (layout pattern) of a defect evaluation pattern for detecting a short circuit.

FIG. 12B is a layout pattern of a defect evaluation pattern for detecting a disconnection and a short circuit.

FIG. 12C is a sectional view along a line C-C of defect evaluation pattern main portions 503, 504, 508, and 510 in FIG. 12A and FIG. 12B, FIG. 12D is a sectional view along a line D-D of defect evaluation pattern electrode portions 501, 502, 506, 507, 509 in FIG. 12A and FIG. 12B, and FIG. 12E is a sectional view along a line E-E of a well electrode portion 505 and 511 in FIG. 12A and FIG. 12B.

Hereinafter a layout of each element will be explained.

As shown in FIG. 12A, the evaluation pattern for detecting a short circuit is composed of electrodes 501 and 502 to which a circuit tester needle for measurement contacts, a pattern 503 extended from the electrode 501, and a pattern 504 extended from the electrode 502, and the pattern 503 and the pattern 504 are arranged not to be contacted with each other. Further, an electrode 505 is connected to a well 513 and a diffusion layer 519, and when the well 513 and the diffusion layer 519 are, for example n-type semiconductor layers, the electrode 505 is also formed of a layer of a silicided n-type semiconductor. Meanwhile, the electrode 501, the electrode 502, the pattern 503, and the pattern 504 are formed of layers of silicided p-type semiconductors. A well potential is then set by the electrode 505, and a current is measured by applying a voltage between the electrode 501 and the electrode 502, so that an electrical fault can be measured. In this case, when the current become a certain threshold or more, it is determined that the pattern 503 and the pattern 504 are short-circuited, resulting in a detection of a short circuit fault. Further, the evaluation pattern for detecting a disconnection and a short shown in FIG. 12B is composed of a pattern 508 which connects an electrode 506 to an electrode 507, and a pattern 510 extended from an electrode 509, and the pattern 508 and the pattern 510 are arranged not to be contacted. In addition, an electrode 511 is connected to the well 513 and the diffusion layer 519, and when the well 513 and the diffusion layer 519 are, for example the n-type semiconductor layers, the electrode 511 is also formed of a layer of a silicided n-type semiconductor. Meanwhile, the electrode 506, the electrode 507, the pattern 508, the pattern 509, and the pattern 510 are formed of a layer of a silicided p-type semiconductor. A well potential is then set by the electrode 511, and a current is measured by applying a voltage between the electrode 506 and the electrode 507, and when the current is a threshold or less, it is determined that a disconnection is occurred in somewhere in the pattern 508, resulting in a detection of a disconnection fault. Additionally, a current is measured by applying a voltage between the electrode 506 or the electrode 507, and the electrode 509, and when a current become a certain threshold or more, it is determined that there is a short circuit between the pattern 508 and the pattern 510, resulting in a detection of a short circuit fault.

Next, a cross sectional structure of each element will be explained. As shown in FIG. 12C, the main portion of the diffusion layer pattern for fault evaluation (diffusion layer patterns 503, 504, 508, and 510) is composed of a well 513 formed on a semiconductor substrate 512, an active region 514, a silicon oxide 515 for device isolation that is formed in the perimeter of the active region 514 and separates the active regions 514, a diffusion layer 516 with the opposite conductivity type formed in the upper part of the well 513, a low resistance silicide layer 517 formed on the surface of the diffusion layer 516, and a protective film 518 for preventing a surface leakage between the active regions 514. When the well 513 is, for example, an n-type semiconductor layer, the diffusion layer 516 is formed of a p-type semiconductor layer. Meanwhile, as shown in FIG. 12D, the electrode portion of the defect evaluation pattern (the electrode 501, electrode 502, electrode 506, electrode 507, and electrode 509) is composed of the well 513 formed on the semiconductor substrate 512, the silicon oxide 515 for device isolation formed in the perimeter of the well 513, the diffusion layer 516 with the opposite conductivity type formed in the upper part of the well 513, and the low resistance silicide layer 517 formed on the surface of the diffusion layer 516. Further, as shown in FIG. 12E, the well electrode portion (the electrode 505, electrode 511) is composed of the well 513 formed on the semiconductor substrate 512, the silicon oxide 515 for device isolation formed in the perimeter of the well 513, the diffusion layer 519 with the same conductivity type as that of the well 513 formed in the upper part of the well 513, and the low resistance silicide layer 517 formed on the surface of the diffusion layer 519.

When using such a method as described above, theoretically, the fault generated in the device isolation forming process can be electrically detected (refer to Patent Publication No. 2551202 (Japanese Laid-open Patent Application No. H4-29349) and Japanese Laid-Open Patent Application Publication No. 2004-31859).

According to a conventional example, however, with the advance of a microfabrication, it has been difficult to accurately detect the fault by using the structure of the electrode portion of the defect evaluation pattern shown in FIG. 12D. This reason will be explained using FIG. 13.

FIG. 13 is a sectional view when contacting a probe needle 520 for electrical characteristic measurement to the electrode shown in FIG. 12D. The silicide layer 517 formed with a material harder than aluminum or the like is formed on an uppermost surface of the electrode portion. For this reason, unless a sufficient stylus pressure is given to the probe needle 520 for electrical characteristic measurement to be contacted to the electrode portion, a desired voltage would not be applied to the electrode, so that an accurate measurement may not be achieved. Meanwhile, when a large stylus pressure is applied thereto so that the desired voltage may be applied to the electrode, the silicide layer 517 and the diffusion layer 516 may be damaged by the pressure, resulting in a junction leakage 521. Therefore, there has been a problem that the electrical fault measurement could not be performed because of a short circuit between the needle 520 and the wells 513.

The characteristics of an initial junction leakage current and a junction leakage current in a condition after proving it with the probe needle 10 times are shown in FIG. 14. A horizontal axis and a vertical axis represent an applied voltage of the diffusion layer 516 to a substrate, and the amount of currents flowing into the substrate, respectively. In the initial state, the junction leakage current exhibits a normal pn junction reverse bias characteristic. A junction withstand voltage is approximately 9.5 V. The leakage current when 3 V is applied is 3×10⁻¹¹ A. Meanwhile, after repeating the probing 10 times, it becomes 2×10⁻⁹ A when 3 V is applied, resulting in an increase in approximately double-digit current. This pattern is the evaluation pattern for detecting a short circuit as shown in FIG. 12A, and a current specification when 3 V is applied is set at 1×10⁻¹⁰ A or less, but it will be detected as a dummy fault due to an increase in junction leakage current by probing, thereby making it difficult to perform accurate fault detection. These are caused by a thickness of the silicide layer 517 and a depth of the diffusion layer 516 which are reduced to 30 to 60 nm and 150 to 200 nm, respectively, with the microfabrication of the element, and the further the microfabrication advances, the more serious this problem would be.

Meanwhile, there is also a method that after depositing an insulating film on an electrode, a contact hole is formed into the insulating film, a metal electrode composed of aluminum is further formed thereon, the electrode and the metal electrode are electrically connected via the contact hole, thereby making the probe needle not to be directly contacted to the silicide layer. Although this is excellent as a method of suppressing the junction leakage current due to probing, the number of processes of forming the contact through the metal electrode is increased, and an increase in process fault in those processes will be included. Therefore, an object of making it possible to manufacture the semiconductor device with as few process steps as possible, using the manufacturing process to which the defective management is performed as a target, may not be achieved.

### SUMMARY OF THE INVENTION

An object of the present invention is to provide a semiconductor device which does not produce a junction leakage current across a pn junction formed under a silicide layer even when a direct probing to an electrode formed of the silicide layer is performed, and has an element for evaluation which can be manufactured with as few process steps as possible, and a manufacturing method thereof.

In order to achieve the above object, there is provided a semiconductor device according to a first aspect of the present invention including an element for evaluation, wherein the element for evaluation includes a device isolation region, a first diffusion layer region formed adjacent to the device isolation region, an electrode for probe formed to be electrically connected to the first diffusion layer region, a semiconductor region which is formed under the first diffusion layer region to be contacted to the first diffusion layer region, and has a conductivity type different from that of the first diffusion layer region, and an evaluation pattern which is formed to be electrically connected to the electrode for probe, and includes at least a part of the first diffusion layer region, and wherein a second diffusion layer region which has the same conductivity type as that of the first diffusion layer region is selectively formed under the first diffusion layer region formed under the electrode for probe to be contacted to the first diffusion layer region and the semiconductor region.

According to this constitution, a second pn junction which is an interface between the second diffusion layer region under the electrode region for probe and the semiconductor region is formed in a position deeper than a first pn junction which is a surface between the first diffusion layer region composing the evaluation pattern and the semiconductor region. Therefore, when a probe needle is contacted to the electrode for probe and a current is then applied to an evaluation pattern region in order to evaluate a fault produced in forming the device isolation region, an adverse effect of giving a physical shock to the second pn junction in contacting the prove needle is reduced, thereby making it possible to prevent a pn junction leakage current from being produced in the second pn junction. Thus, accurate fault detection can be achieved. In addition, it is not necessary to form a particular electrode structure for absorbing the physical shock generated when the prove needle is contacted thereto in the electrode region for probe, that makes it possible to manufacture the element for evaluation with as few process steps as possible.

There is provided a semiconductor device according to a second aspect of the present invention, wherein in the semiconductor device of the first aspect, a high impurity concentration of the second diffusion layer region is higher than that of the semiconductor region.

According to this constitution, the high impurity concentration of the second diffusion layer region will certainly exceed that of the semiconductor region, thereby making it possible to form the stable second pn junction. Therefore, accurate fault detection can be achieved.

There is provided a semiconductor device according to a third aspect of the present invention including an element for evaluation, wherein the element for evaluation includes a device isolation region, a diffusion layer region formed adjacent to the device isolation region, an electrode for probe formed to be electrically connected to the diffusion layer region, a semiconductor region which is formed under the diffusion layer region so as to contact to the diffusion layer region, and has a conductivity type different from that of the diffusion layer region, and an evaluation pattern which is formed to be electrically connected to the electrode for probe, and includes at least a part of the diffusion layer region, and wherein a layer thickness of the diffusion layer region which is formed under the electrode for probe is formed to be thicker than that of the diffusion layer region which composes the evaluation pattern.

According to this constitution, a second pn junction which is an interface between the diffusion layer region under the electrode for probe and the semiconductor region is formed in a position deeper than a first pn junction which is an interface between the diffusion layer region composing the evaluation pattern and the semiconductor region. Therefore, when a probe needle is contacted to the electrode for probe and a current is then applied to an evaluation pattern region in order to evaluate a fault produced in forming the device isolation region, an adverse effect of giving a physical shock to the second pn junction in contacting the prove needle is reduced, thereby making it possible to prevent an pn junction leakage current from being produced. Thus, accurate fault detection can be achieved. In addition, it is not necessary to form a particular electrode structure for absorbing the physical shock generated when the prove needle is contacted thereto in the electrode region for probe, that makes it possible to manufacture the element for evaluation with as few process steps as possible.

There is provided a semiconductor device according to fourth through sixth aspects of the present invention, wherein in the semiconductor devices of the respective first through third aspects, the element for evaluation is formed on a semiconductor substrate, a conductivity type of the semiconductor region and a conductivity type of the semiconductor substrate are different form each other, and at least a part of semiconductor region surrounds the sides and the bottom of the diffusion layer region formed under the electrode for probe, or the second diffusion layer region.

According to this constitution, when the conductivity type of the semiconductor substrate is the same as that of the diffusion layer region or the second diffusion layer region, at least a part of the semiconductor region is formed so as to surround the sides and the bottom of the diffusion layer region or the second diffusion layer region formed under the electrode for probe, and the diffusion layer region or the second diffusion layer region is not electrically connected to the semiconductor substrate, so that it is possible to prevent a leakage current from flowing to the semiconductor substrate from the diffusion layer region or the second diffusion layer region formed under the electrode for probe.

There is provided a semiconductor device according to seventh through twelfth aspects of the present invention, wherein, in the semiconductor devices of the respective first through sixth aspects, a compound which is composed of a main constitution element of the semiconductor region and a metallic element is formed on the diffusion layer region or the first diffusion layer region.

According to this constitution, a probe needle is contacted to the compound which is composed of the main constitution element of the semiconductor region formed on the diffusion layer region or the first diffusion layer region, and the metallic element, so that the evaluation can be achieved, thereby making it possible to compose the electrode region for probe with a simple constitution.

There is provided a semiconductor device according to a 13th aspect of the present invention, wherein in the semiconductor device of the seventh aspect, the main constitution element of the semiconductor region is silicon, and the metallic element is selected from at least one of titanium, cobalt, nickel, tungsten, and molybdenum.

There is provided a method of manufacturing the semiconductor device according to a 14th aspect of the present invention including the steps of forming a device isolation region in a semiconductor substrate, forming a semiconductor region which has the same conductivity type as that of the semiconductor substrate in at least a part of the semiconductor substrates, forming a first diffusion layer region which has a conductivity type different from that of the semiconductor region in at least a part of region in the semiconductor substrate so as to contact to the device isolation region, after or before forming the first diffusion layer region, forming a second diffusion layer region which has a conductivity type different from that of the semiconductor substrate in at least a part of region in the semiconductor substrate so as to contact to the semiconductor region, forming a silicide region on the first diffusion layer region, and forming an electrode for probe in at least a part of region of the silicide region, wherein the second diffusion layer region is selectively formed under the first diffusion layer region formed under the electrode for probe so as to contact to the first diffusion layer region.

According to this constitution, it is possible to easily manufacture the semiconductor device according to the first or the third aspect of the present invention. Incidentally, in order to manufacture the semiconductor device according to the third aspect, what is necessary is just to manufacture the first diffusion layer region and the second diffusion layer region so as to be formed into one diffusion layer region.

There is provided a method of manufacturing the semiconductor device according to a 15th aspect of the present invention including the steps of forming a device isolation region in a semiconductor substrate, forming a semiconductor region which has a conductivity type different from that of the semiconductor substrate in at least a part of the semiconductor substrates, forming a first diffusion layer region which has the same conductivity type as that of the semiconductor substrate in at least a part of region in the semiconductor substrate so as to contact to the device isolation region, after or before forming the first diffusion layer region, forming a second diffusion layer region which has a conductivity type different from that of the semiconductor region in at least a part of region in the semiconductor substrates so as to contact the semiconductor region and so as for its bottom to be located upper than the bottom of the semiconductor region, forming a silicide region on the first diffusion layer region, and forming an electrode for probe in at least a part of region of the silicide region, wherein the second diffusion layer region is selectively formed under the first diffusion layer region formed under the electrode region for probe so as to contact to the first diffusion layer region.

According to this constitution, it is possible to easily manufacture the semiconductor device according to the first or the third or the fourth through sixth aspects of the present invention. Incidentally, in order to manufacture the semiconductor device according to the third aspect, what is necessary is just to manufacture the first diffusion layer region and the second diffusion layer region so as to be formed into one diffusion layer region.

There is provided a method of manufacturing the semiconductor device according to 16th and 17th aspects of the present invention, wherein in the semiconductor devices of the respective 14th and 15th aspects, the process for forming the semiconductor region includes a process for forming a mask in a region where the second diffusion layer region is formed.

According to this constitution, since the region where the second diffusion layer region is formed is covered with the mask in forming the semiconductor region, the semiconductor region is not formed. For this reason, an impurity diffusion, such as ion implantation, is performed to the semiconductor substrate at relatively low high impurity concentration in forming the second diffusion layer region, so that the second diffusion layer region can be formed. Therefore, that makes it possible to reduce an amount of impurities to be introduced for forming the second diffusion layer region.

### BRIEF DESCRIPTION OF THE DRAWINGS

FIG. 1A is a plan view of an area in which an evaluation element for evaluating a presence of a fault by detecting a short circuit between patterns is formed in a semiconductor device according to a first to fourth embodiments of the present invention;

FIG. 1B is a plan view of an area in which an evaluation element for evaluating a presence of a fault by detecting a short circuit between patterns or a disconnection thereof is formed in a semiconductor device according to a modification of the first embodiment of the present invention;

FIG. 2A and FIG. 2B are sectional views of C-C and D-D, respectively, in the plan view of the semiconductor device according to the first embodiment of the present invention;

FIG. 3A through FIG. 3D are process sectional views for explaining a method of manufacturing the semiconductor device according to the first and the second embodiments of the present invention;

FIG. 4A and FIG. 4B are process sectional views for explaining the method of manufacturing the semiconductor device according to the first and the second embodiments of the present invention;

FIG. 5 is a graph showing a junction leakage current characteristic evaluated in the semiconductor device according to the first embodiment of the present invention;

FIG. 6 is an enlarged view of the semiconductor device in the plan view according to the first embodiment the present invention;

FIG. 7A and FIG. 7B are sectional views of C-C and D-D, respectively, in the plan view of the semiconductor device according to the second embodiment of the present invention;

FIG. 8A through FIG. 8D are process sectional views for explaining a method of manufacturing the semiconductor device according to the third embodiments of the present invention;

FIG. 9A and FIG. 9B are sectional views of C-C and D-D, respectively, in the plan view of the semiconductor device according to the fourth embodiment of the present invention;

FIG. 10A through FIG. 10D are process sectional views for explaining a method of manufacturing the semiconductor device according to the fourth embodiments of the present invention;

FIG. 11A and FIG. 11B are process sectional views for explaining the method of manufacturing the semiconductor device according to the fourth embodiments of the present invention;

FIG. 12 is a plane schematic diagram of a semiconductor device and a partially enlarged cross sectional view of a semiconductor device in the middle of a manufacturing process according to a conventional art;

FIG. 13 is a partially enlarged cross sectional view of the semiconductor device when contacting a probe needle in the semiconductor device according to the conventional art; and

FIG. 14 is a graph showing a junction leakage current characteristic of the semiconductor device according to the conventional art.

### DETAILED DESCRIPTION OF PREFERRED EMBODIMENTS

Hereafter, referring to the drawings, each embodiment of the present invention will be explained.

### First Embodiment

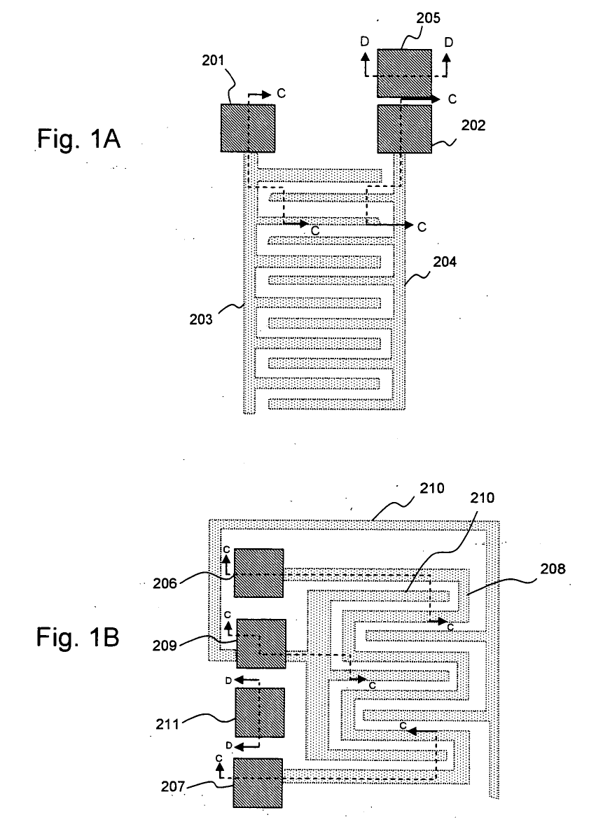

A semiconductor device according to a first embodiment of the present invention and a manufacturing method thereof will be explained based on FIG. 1 through FIG. 6.

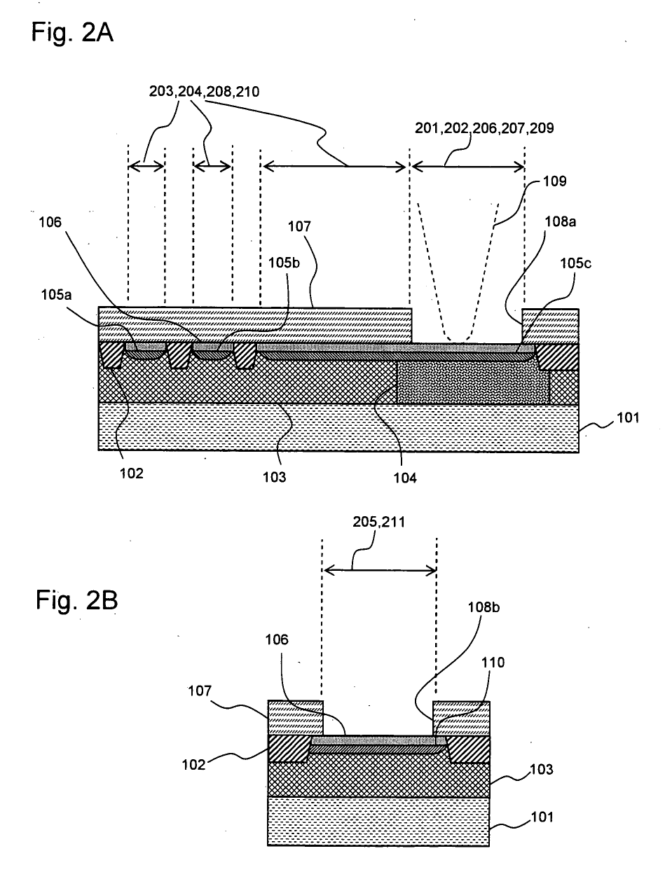

First, a constitution of the semiconductor device according to this embodiment will be explained using FIG. 1A, FIG. 2A, and FIG. 2B.

FIG. 1A is a plan view of an area in which an evaluation element for evaluating a presence of a fault by detecting a short circuit between patterns is formed in the semiconductor device according to the first embodiment of the present invention, and FIG. 2A and FIG. 2B are sectional views of lines C-C and D-D in FIG. 1A, respectively.

As shown in FIG. 1A, the evaluation element which composes the semiconductor device according to this embodiment includes an electrode 201 which composes a first electrode for probe, an electrode 202 which composes a second electrode for probe, a first evaluation pattern 203 which is electrically connected to the electrode 201, a second evaluation pattern 204 which is electrically connected to the electrode 202, and an electrode 205 which composes a third electrode for probe. Here, the first evaluation pattern 203 and the second evaluation pattern 204 are formed not to be contacted to each other. Incidentally, any circuit element or the like other than the evaluation element may be formed in the semiconductor device according to this embodiment.

FIG. 2A is a sectional view of the first or the second electrode for probe and the first or the second evaluation pattern.

The first or the second evaluation pattern 203, 204 includes n-type diffusion layers 105a, 105b and 105c (first diffusion layer region) which are formed adjacent to a device isolation oxide film 102 (device isolation region) formed in a main surface of a p-type semiconductor substrate 101, and a silicide layer 106 which is formed on the n-type diffusion layers 105a, 105b, and 105c. Further, the first or the second electrode for probe includes the silicide layer 106 which is formed on the n-type diffusion layer 105c formed adjacent to the device isolation oxide film 102, and an opening for probe 108a which is formed into an interlayer dielectric 107 on the silicide layer 106. A p-type well region 103 (semiconductor region) is formed under the n-type diffusion layers 105a, 105b, and 105c so as to contact to the n-type diffusion layers 105a, 105b, and 105c. In addition, an n-type well region 104 (second diffusion layer region) is selectively formed under the n-type diffusion layer 105c formed under the first or the second electrode for probe so as to contact to the n-type the diffusion layer 105c and the p-type well region 103. Here, although the p-type semiconductor substrate 101 and the n-type well region 104 are contacted, such a constitution as the p-type well region 103 exists between the p-type semiconductor substrate 101 and the n-type well region 104 may be employed.

Incidentally, the silicide layer 106 exposed to the opening for probe 108a is used as the electrodes 201 and 202 here, and is electrically connected to the n-type diffusion layer 105c. In addition, the silicide layer 106, the n-type diffusion layers 105a and 105b, and a part of the n-type diffusion layer 105c, which are isolated by the device isolation oxide film 102 and formed under the interlayer dielectric 107, are used as the first or the second evaluation pattern 203, 204.

Incidentally, when the n-type diffusion layer 105c and the n-type well region 104 are considered as one combined n-type diffusion layer, it can be said that a film thickness of the combined n-type diffusion layer formed under the first or the second electrode region for probe is thicker than a film thickness of the n-type diffusion layers 105a and 105b formed under the first or the second evaluation pattern area.

Additionally, FIG. 2B shows a sectional view of the third electrode for probe.

The third electrode for probe includes the silicide layer 106 which is formed on a p-type diffusion layer 110 formed adjacent to the device isolation oxide film 102 (device isolation region) formed in the main surface of the p-type semiconductor substrate, and an opening for probe 108b which is formed into the interlayer dielectric 107 on the silicide layer 106. Incidentally, the silicide layer 106 exposed to the opening for probe 108b is used as the electrode 205 here.

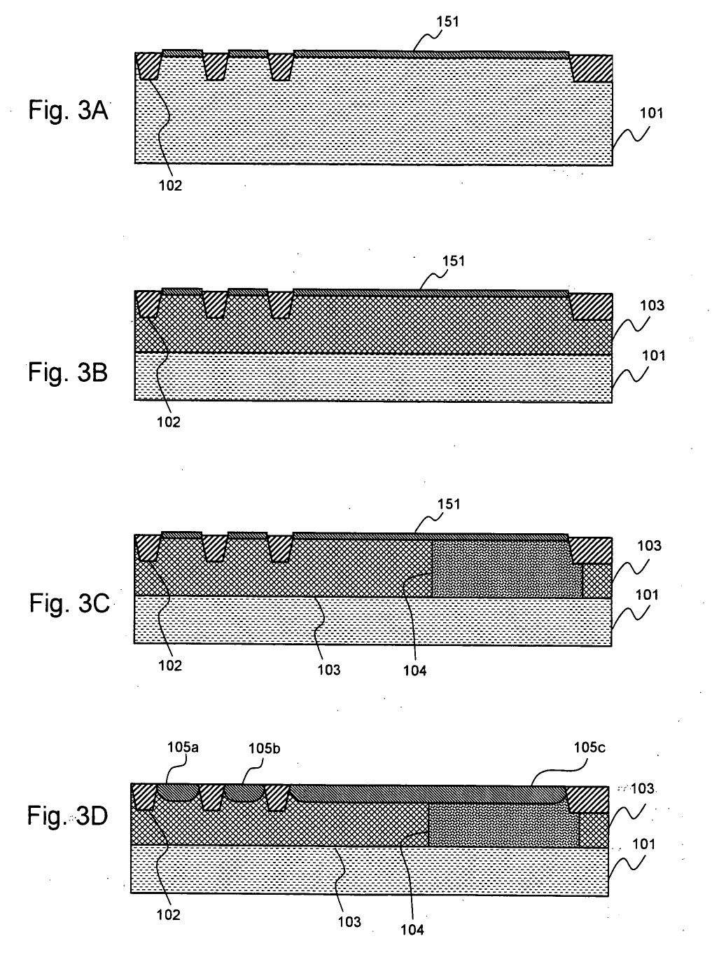

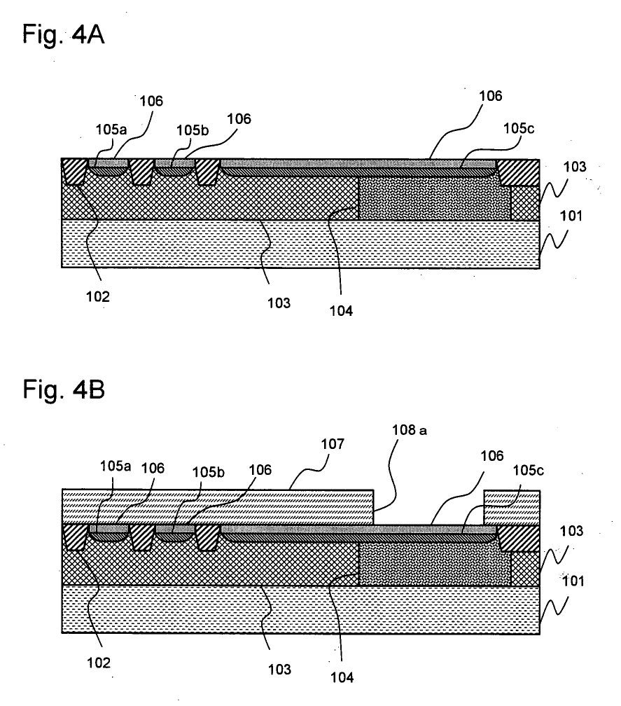

Next, the manufacture method of the semiconductor device according to this embodiment will be explained using FIG. 3A through FIG. 3D, FIG. 4A, and FIG. 4B.

FIG. 3A through FIG. 3D, FIG. 4A, and FIG. 4B are sectional views of the main processes for explaining the manufacturing process of the first or the second electrode for probe and the first or the second evaluation pattern in the evaluation element which composes the semiconductor device according to this embodiment.

First, as shown in FIG. 3A, the device isolation oxide film 102 is formed in the main surface of the p-type semiconductor substrate 101 using an STI (Shallow Trench Isolation) method or the like. A silicon oxide 151 is formed in a portion where the device isolation oxide film 102 is not formed on the main surface of the p-type semiconductor substrate 101.

Next, as shown in FIG. 3B, boron ions at a dose of 1×10¹³ are implanted into a whole surface of the p-type semiconductor substrate 101 at an acceleration energy of 250 keV to form the p-type well region 103. In addition to this, boron ions at a dose of 1×10¹³ are implanted at an acceleration energy of 100 keV as an N-channel stopper in a manner similar to that. These implantation energies and doses are not limited those described above, and in order to form the p-type well region 103 with a desired concentration and depth, they can generally be selected in a range of implantation energy of 100 to 500 keV and of dose of 1×10¹² to 1×10⁴. In addition, a tilt angle of approximately 7 degrees is preferable for these ion implantations, but it is not limited to this. Further, the ion implantations may be performed separately at implantation conditions with different tilt angles if needed, and an implantation for threshold control of a transistor may also be added.

Next, as shown in FIG. 3C, the n-type well region 104 is formed in a part of the p-type semiconductor substrate 101 by combining a resist pattern formation according to a normal lithography and a phosphorus ion implantation. Meanwhile, the n-type well region 104 is formed only under the first and the second electrodes for prove. The electrode regions correspond to the electrodes 201 and 202 in FIG. 1A. In the phosphorus ion implantation, phosphorus ions at a dose of 3×10¹³ are implanted at an acceleration energy of 600 keV. In addition to this, phosphorus ions at a dose of 3×10¹³ are implanted at an acceleration energy of 250 keV as a P-channel stopper in a manner similar to that. These implantation energies and doses are not limited those described above, and in order to form the n-type well region 104 with a desired concentration and depth, they can generally be selected in a range of implantation energy of 300 to 900 keV and of dose of 1×10¹² to 5×10¹⁴. Since the n-type well region 104 has a conductivity type opposite to the p-type well region 103, it is necessary to re-implant impurities with a high impurity concentration equal to or more than that of the impurities for forming the p-type well region 103. The high impurity concentration of the n-type well region 104 therefore requires higher impurity concentration for forming the p-type well region 103 by two times or more in general. In addition, the tilt angle of approximately 7 degrees is preferable for these ion implantations, but it is not limited to this. Further, the ion implantations may be performed separately at the implantation conditions with different tilt angles if needed, and an implantation for threshold control of a transistor may also be added. Incidentally, although the n-type well region 104 is formed so that the bottom of the n-type well region 104 may reach the p-type semiconductor substrate 101 here, an ion implantation energy in forming the n-type well region 104 may be suppressed low for the bottom of the n-type well region 104 not to reach the p-type semiconductor substrate 101.

Next, as shown in FIG. 3D, by combining a resist pattern formation according to a normal lithography and an ion implantation, the n-type diffusion layers 105a, 105b, and 105c are formed in a part of the p-type semiconductor substrate 101. The n-type diffusion layers are formed self-alignedly relative to the device isolation oxide film 102. As a condition for the ion implantation, As ions at a dose of 4×10¹⁵ are implanted at an acceleration energy of 50 keV. In addition to this, phosphorus ions at a dose of approximately 4×10¹³ may be implanted at an acceleration energy of 40 keV. these implantation energies are not limited to those described above, but those may be selected freely to form the n-type diffusion layers 105a, 105b, and 105c with a desired depth. Meanwhile, in order to suppress a contact resistance, an implantation dose of approximately 1×10¹⁵ to 8×10¹⁵ in total may preferably be implanted by combining As ions, P ions, or the like. In addition, the tilt angle of approximately 7 degrees is preferable for these ion implantations, but it is not limited to this. Further, the ion implantations may be performed separately at the implantation conditions with different twist angles if needed. In addition, in order to form the third electrode for probe in FIG. 2B, the p-type diffusion layer 110 which is not shown is formed in a part of the p-type semiconductor substrate 101. The p-type diffusion layer 110 is formed by implanting boron ions at a dose of 4×10¹⁵ at an acceleration energy of 15 keV. In addition to this, boron ions at a dose of approximately 4×10¹³ may be implanted at an acceleration energy of 40 keV. These implantation energies or doses are not limited to the conditions described above similar to the As or phosphorus implantation in forming the n-type diffusion layers 105a, 105b, and 105c, and those may be selected freely to form the p-type diffusion layer 110 with a desired depth and concentration.

Next, as shown in FIG. 4A, a self aligned silicide process using Co, Ti, nickel, or the like is performed, and the silicide layer 106 is formed on the n-type diffusion layers 105a, 105b, and 105c, and the p-type diffusion layer 110 in FIG. 2B. When forming, for example a Co silicide, a Co metal thin film with a thickness of approximately 10 nm is formed, and then a TiN thin film is continuously formed in a thickness of 10 to 20 nm, unreacted Co is removed with an acid after a heat treatment at 400 to 500 degrees C, and a heat treatment at 700 to 800 degrees C is further performed, so that the silicide layer 106 with a thickness of approximately 30 to 80 nm can be formed.

Next, as shown in FIG. 4B, the interlayer dielectric 107 is formed on the p-type semiconductor substrate 101 using a plasma CVD method or the like. As the interlayer dielectric 107, a silicon oxide, a SIOF film obtained by introducing fluorine into a silicon oxide, a silicon nitride, an organic thin film, such as polyimide or the like may be used. Next, a part of the interlayer dielectric 107 is etched by combining a resist pattern formation according to a normal lithography and a dry etching, and then the opening for probe 108a and the opening for probe 108b in FIG. 2B are formed in a required region, so that the formation of the semiconductor device is finally completed.

The silicide layer 106 exposed to the opening for probe 108a is corresponds to the electrodes 201 and 202 in FIG. 1A, and the silicide layer 106 exposed to the opening for probe 108b corresponds to the electrode 205 in FIG. 1A. When the polyimide or the like is used as the interlayer dielectric 107, the openings for probe 108a and 108b can be formed only by a coat, development, and cure.

In order to evaluate the semiconductor device according to this embodiment, a probe needle 109 is contacted onto the silicide layer 106 exposed to a portion where the opening for probe 108a is formed as shown in FIG. 2A.

The probe needle is contacted onto the opening for probe 108b corresponding to the electrode 205, so that the well potential is set; and different probe needles are contacted on to the opening for probe 108a corresponding to the electrode 201 and the opening for probe 108a corresponding to the electrode 202, respectively, and the voltage is then applied between the electrode 201 and the electrode 202, so that a current flowing between the electrode 201 and the electrode 202 is measured, thereby making it possible to measure the electrical fault caused during the device isolation forming process. In this case, when the current becomes a certain threshold or more, it is determined that the first evaluation pattern 203 and the second evaluation pattern 204 are short-circuited, resulting in a detection of a short circuit fault.

According to the semiconductor device of this embodiment, in the element for evaluation which composes the semiconductor device, the n-type well region 104 with the same conductivity type as that of the n-type diffusion layer 105c is formed under the n-type diffusion layer 105c. An electrical pn junction is therefore formed not between the n-type diffusion layer 105c and the n-type well region 104, but between the n-type well region 104 and the p-type semiconductor substrate 101. As explained above, the depths of the silicide layer 106 and the n-type diffusion layer 105c are 30 to 60 nm and 150 to 200 nm, respectively, whereas the n-type well region 104 is deeply formed to be 1000 to 1500 nm. Since the n-type diffusion layer 105c and the n-type well region 104 are adjacently formed, leading a state of being electrically connected to each other.

In addition, as explained above, since the silicide layer 106 is harder as compared with aluminum or the like, unless the probe needle 109 for electrical characteristic measurement is contacted to the silicide layer 106 with sufficient stylus pressure, a desired voltage would not be applied to the silicide layer 106, causing an inaccurate measurement. On the contrary, when a high stylus pressure is applied thereto so as to be able to apply the desired voltage to the electrode, the silicide layer 106 and the n-type diffusion layer 105c are damaged by the pressure, causing the fault. However, when using the semiconductor device according to this embodiment, since the n-type diffusion layer 105c and the n-type well region 104 are electrically connected even when the fault would occur in the n-type diffusion layer 105c, the electrical pn junction will be provided between the n-type well region 104 and the p-type semiconductor substrate 101. Since the n-type well region 104 has the depth of 1000 to 1500 nm as mentioned above, the damage does not reach this depth, so that the junction leakage current is not produced. Therefore, that makes it possible to perform the electrical fault detection correctly.

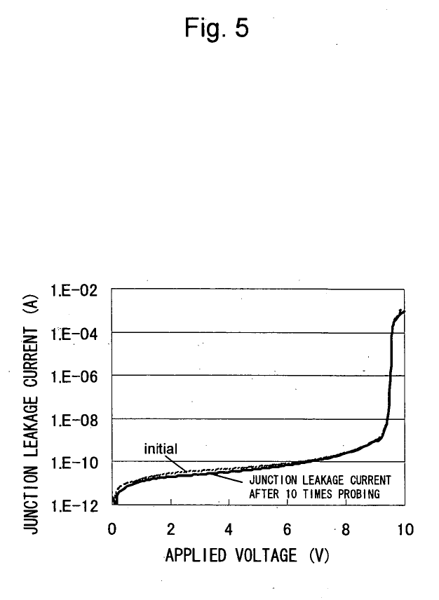

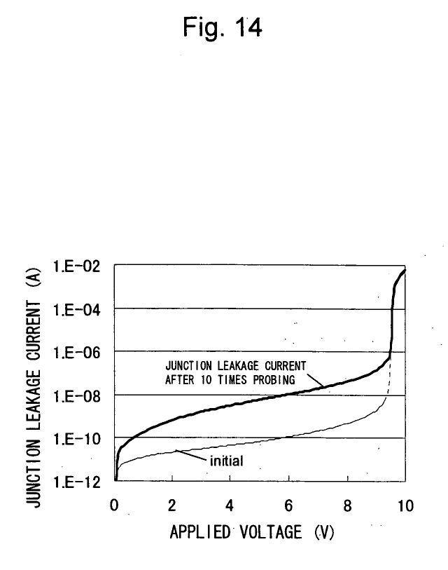

A junction leakage current characteristic is shown in FIG. 5 when contacting the probe needle to the silicide layer 106 in the semiconductor device according to this embodiment. A horizontal axis and a vertical axis represent an applied voltage of the n-type diffusion layer 105c to the p-type substrate 101, and the amount of currents flowing into the p-type substrate 101, respectively. A broken line and a solid line represent an initial state (initial junction leakage current characteristic) and a junction leakage current characteristic after probing 10 times, respectively. These measurement conditions are the same as those shown in FIG. 14. The characteristic after probing 10 times is almost the same as the characteristic of the initial state (initial), and an increase in the leakage current due to probing shown in FIG. 14 is not seen. Therefore, by employing this embodiment, it becomes possible to perform the electrical fault detection correctly without generating the junction leakage current.

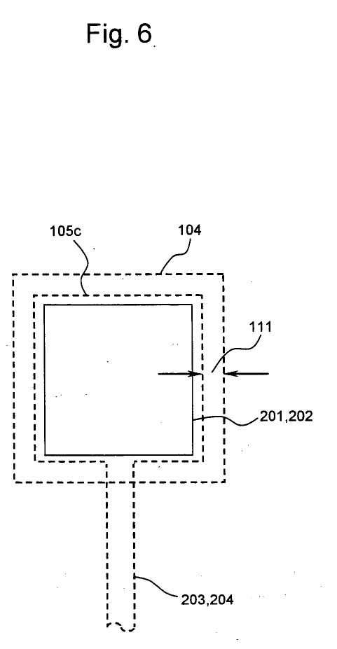

In addition, the electrode 201 or 202 which composes the first or the second electrode for probe in FIG. 1A may be configured as shown in FIG. 6. FIG. 6 is a plan view which expands the portion of the electrode 201 or the electrode 202 which composes the first or the second electrode for probe in FIG. 1A.

Concretely, the n-type diffusion layer region 105c is the electrode for probe, but preferably, the n-type well forming region 104 is equal to the n-type diffusion layer region 105c in size, or is larger than that to some extent in size including the n-type diffusion layer region 105c, except a portion connected to the evaluation patterns 203 and 204. This is because of accommodating the fault within the n-type well forming region 104, wherever the fault may occur in the n-type diffusion layer region 105c. In this embodiment, 1 micrometer is used as a margin A111, but it is not limited to this.

In this embodiment, the p-type semiconductor substrate is employed, but it is not overemphasized that an n-type semiconductor substrate may be used. In addition, the n-type diffusion layer is formed after forming the p-type well, but on the contrary, the p-type diffusion layer may be formed after forming the n-type well as will be explained in detail in a second embodiment. Additionally, these may be simultaneously formed on the same semiconductor substrate.

### Modification of the First Embodiment

Hereafter, referring to the drawings, a semiconductor device and a manufacturing method thereof according to a modification of the first embodiment of the present invention will be explained.

First, a constitution of the semiconductor device according to one modification of this embodiment will be explained using FIG. 1B, FIG. 2A, and FIG. 2B.

FIG. 1B is a plan view of an area in which an evaluation element for evaluating a presence of a fault by detecting a short circuit between patterns or a disconnection thereof is formed in the semiconductor device according to the one modification of the first embodiment of the present invention, and FIG. 2A and FIG. 2B are sectional views of lines C-C and D-D in FIG. 1B, respectively.

As shown in FIG. 1B, the evaluation element which composes the semiconductor device according to this modification includes the electrode 206 which composes the first electrode for probe, the electrode 207 which composes the second electrode for probe, the electrode 209 which composes the third electrode for probe, the first evaluation pattern 208 which is electrically connected to the electrode 206 and the electrode 207, the second evaluation pattern 210 which is electrically connected to the electrode 209, and an electrode 211 which composes a fourth electrode for probe. Here, the first evaluation pattern 208 and the second evaluation pattern 210 are formed not to be contacted to each other. Incidentally, any circuit element or the like other than the evaluation element may be formed in the semiconductor device according to this modification.

FIG. 2A and FIG. 2B are similar to those in the first embodiment. Incidentally, the silicide layer 106 exposed to the opening for probe 108 is used as the electrodes 206, 207, and 209 here. In addition, the silicide layer 106 and the n-type diffusion layers 105a and 105b, and a part of the n-type diffusion layer 105c, which are isolated by the device isolation oxide film 102 and formed under the interlayer dielectric 107, are used as the first or the second evaluation pattern 208, 210. Further, the silicide layer 106 exposed to the opening for probe 108b is used as the electrode 211 here.

In the evaluation element which composes the semiconductor device according to this modification, the manufacturing process of the first or the second electrode for probe and the first or the second evaluation pattern are similar to those of the first embodiment, and they can be manufactured according to the processes shown in FIG. 3A through FIG. 3D, FIG. 4A, and FIG. 4B.

In order to evaluate the semiconductor device according to this modification, the probe needle is contacted onto the opening for probe 108b corresponding to the electrode 211, so that the well potential is set, and different probe needles are contacted onto the opening for probe 108a corresponding to the electrode 206, the opening for probe 108a corresponding to the electrode 207, and the opening for probe 108a corresponding to the electrode 209, respectively, and the voltage is applied between the electrode 206 and the electrode 207, so that a current flowing between the electrode 206 and the electrode 207 is measured, thereby making it possible to measure the electrical fault caused during the device isolation forming process. In this case, when the current becomes a certain threshold or less, it is determined that there is a disconnection in the first evaluation pattern 208, resulting in a detection of a disconnection fault. The voltage is applied between the electrode 206 (or 207) and the electrode 209, so that a current flowing between the electrode 206 (or 207) and the electrode 209 is measured, thereby also making it possible to measure the electrical fault caused during the device isolation forming process. In this case, when the current becomes a certain threshold or more, it is determined that the first evaluation pattern 208 and the second evaluation pattern 210 are short-circuited, resulting in a detection of a short fault.

### Second Embodiment

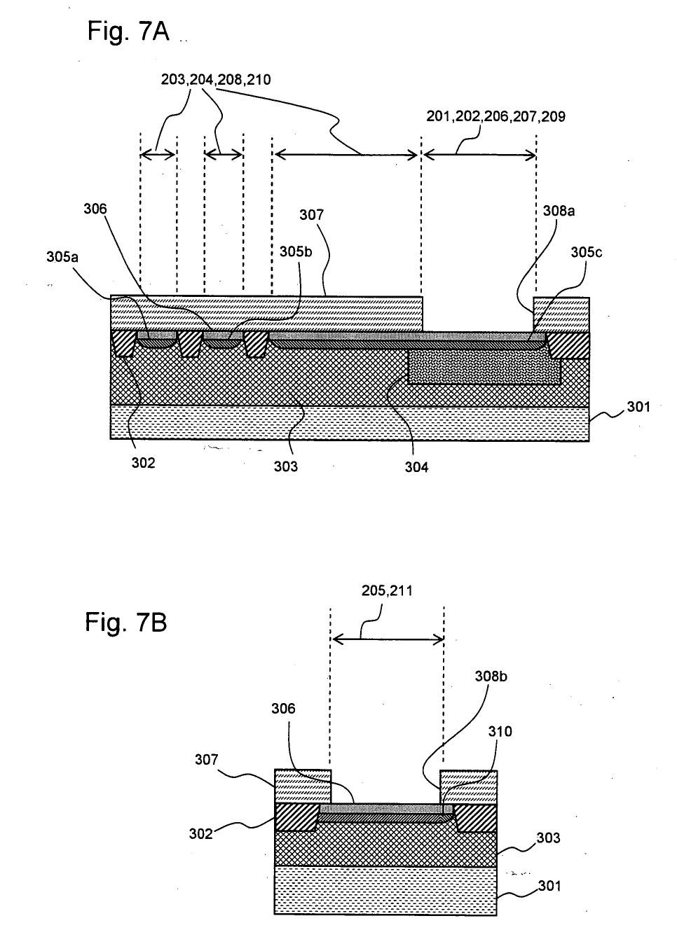

A semiconductor device according to a second embodiment of the present invention and a manufacturing method thereof will be explained based on FIG. 7.

First, a constitution of the semiconductor device according to the second embodiment will be explained using FIG. 1A, FIG. 7A, and FIG. 7B.

FIG. 7A and FIG. 7B are sectional views of lines C-C and D-D in FIG. 1A, respectively.

Hereinafter, the main point of difference of the semiconductor device according to the second embodiment from the semiconductor device according to the first embodiment will be explained.

A plan view of the semiconductor device according to this embodiment is the same as that of the semiconductor device according to the first embodiment, and the main point of difference is a structure of a first or a second electrode for probe and a first or a second evaluation pattern. Concretely, the difference is in forming an n-type well region instead of the p-type well region 103, and a p-type diffusion layer instead of the n-type diffusion layer 104, on a p-type semiconductor substrate.

FIG. 7A is a sectional view of the first or the second electrode for probe.

The first or the second evaluation pattern 203, 204 includes p-type diffusion layers 305a, 305b, and 305c (first diffusion layer region) which are formed adjacent to a device isolation oxide film 302 (device isolation region) formed in a main surface of a p-type semiconductor substrate 301, and a silicide layer 306 formed on the p-type diffusion layers 305a, 305b, and 305c. Further, the first or the second electrode for probe includes the silicide layer 306 which is formed on the p-type diffusion layer 305c formed adjacent to the device isolation oxide film 302, an opening for probe 308a which is formed into an interlayer dielectric 307 on the silicide layer 306, and a p-type well region 304 (second diffusion layer region) which is selectively formed under the p-type diffusion layer 305c formed under the opening for probe 308a so as to contact to the p-type diffusion layer 305c and an n-type well region 303. In addition, the n-type well region 303 (semiconductor region) is formed under the p-type diffusion layers 305a, 305b, and 305c so as to contact to the p-type diffusion layers 305a, 305b, and 305c. Further, the p-type well region 304 (second diffusion layer region) is selectively formed under the p-type diffusion layer 305c formed under the first or the second electrode for probe so as to contact to the p-type diffusion layer 305c and the n-type well region 303. Furthermore, a part of the n-type well region 303 is formed so as to surround the sides and the bottom of the p-type well region 304, and the p-type well region 304 and the p-type semiconductor substrate 301 are not electrically connected.

Incidentally, the silicide layer 306 exposed to the opening for probe 308a is used as the electrodes 201 and 202 here, and is electrically connected to the p-type diffusion layer 305c. In addition, the silicide layer 306, the n-type diffusion layers 305a and 305b, and a part of the n-type diffusion layer 305c, which are isolated by the device isolation oxide film 302 and formed under the interlayer dielectric 307, are used as the first or the second evaluation pattern 203, 204.

FIG. 7B is a sectional view of a third electrode for probe.

The third electrode for probe includes the silicide layer 306 which is formed on an n-type diffusion layer 310 formed adjacent to the device isolation oxide film 302 (device isolation region) formed in the main surface of the p-type semiconductor substrate 301, and an opening for probe 308b which is formed into the interlayer dielectric 307 on the silicide layer 306. Incidentally, the silicide layer 306 exposed to the opening for probe 308b is used as the electrode 205 here.

Hereinafter, a method to manufacture the semiconductor device according to this embodiment which has a cross sectional structure shown in FIG. 7A and FIG. 7B will be explained.

In the processes shown in FIG. 3A through FIG. 3D, FIG. 4A, and FIG. 4B, which have been explained in the first embodiment, the p-type well region 103, the n-type well region 104, the n-type diffusions layers 105a, 105b, and 105c, and the p-type diffusion layer 110 are replaced with the n-type well region 303, the p-type well region 304, the p-type diffusion layers 305a, 305b, and 305c, and the n-type diffusion layer 310, respectively, and further in the process shown in FIG. 3C, an ion implantation energy in forming the p-type well region 304 is suppressed low. By doing in this way, the p-type well region 304 can be selectively formed under the p-type diffusion layer 305c formed under the first or the second electrode for probe so as to contact to the p-type diffusion layer 305c, and the p-type well region 304 can be formed so as to contact to the n-type well region 303 and so as for its bottom to be located upper than the bottom of the n-type well region 303, thereby making it possible to achieve a structure where the p-type well region 304 and the p-type semiconductor substrate 301 are not electrically connected.

According to the semiconductor device of this embodiment, the same effect as that of the semiconductor device according to the first embodiment can be obtained. The constitution shown in FIG. 1B can also be achieved.

### Third Embodiment

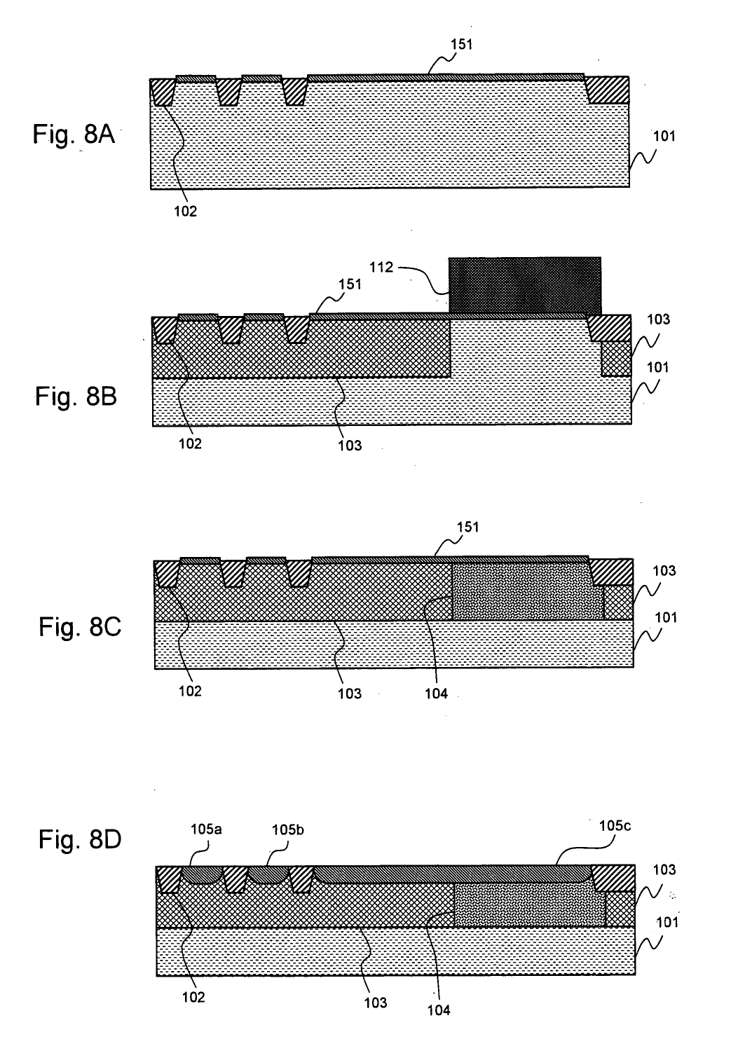

A method of manufacturing a semiconductor device according to a third embodiment of the present invention will be explained based on FIG. 8.

The method of manufacturing the semiconductor device according to this embodiment is the same as that of the first embodiment described above.

Although FIG. 8A through FIG. 8D are sectional views of the main processes for explaining the manufacturing process of a first or a second electrode for probe and a first or a second evaluation pattern in the evaluation element which composes the semiconductor device according to this embodiment, since a process common to that in the method of manufacturing the semiconductor device according to the first embodiment described above is included, the same reference numeral is given to a component common to that in FIG. 3A through FIG. 3D, FIG. 4A, and FIG. 4B.

First, as shown in FIG. 8A, the device isolation oxide film 102 is formed in the main surface of the p-type semiconductor substrate 101 using the STI (Shallow Trench Isolation) method or the like. The silicon oxide 151 is formed in a portion where the device isolation oxide film 102 is not formed on the main surface of the p-type semiconductor substrate 101.

Next, as shown in FIG. 8B, a resist pattern 112 is formed in a region where the n-type well region 104 is formed with a normal lithography, and boron ions at a dose of 1×10¹³ are implanted into a whole surface of the p-type semiconductor substrate 101 at an acceleration energy of 250 keV to form the p-type well region 103. In addition to this, boron ions at a dose of 1×10¹³ are implanted at an acceleration energy of 100 keV as an N-channel stopper in a manner similar to that. These implantation energies and doses are not limited those described above, and in order to form the p-type well region 103 with a desired concentration and depth, they can generally be selected in a range of implantation energy of 100 to 500 keV and of dose of 1×10¹² to 1×10¹⁴. In addition, the tilt angle of approximately 7 degrees is preferable for these ion implantations, but it is not limited to this. Further, the ion implantations may be performed separately at the implantation conditions with different tilt angles if needed, and an implantation for threshold control of a transistor may also be added.

Next, as shown in FIG. 8C, the n-type well region 104 is formed in a part of the p-type semiconductor substrate 101 by combining a resist pattern formation according to a normal lithography and a phosphorus ion implantation. The n-type well region 104 is provided only under the first and the second electrodes for prove. The electrodes correspond to the electrodes 201 and 202 in FIG. 1A. In the phosphorus ion implantation, phosphorus ions at a dose of 1×10¹³ are implanted at an acceleration energy of 600 keV. In addition to this, phosphorus ions at a dose of 1×10¹³ are implanted at an acceleration energy of 250 keV as a P-channel stopper in a manner similar to that. These implantation energies and doses are not limited those described above, and in order to form the n-type well region 104 with a desired concentration and depth, they can generally be selected in a range of implantation energy of 300 to 900 keV and of dose of 1×10¹² to 5×10¹⁴. In addition, the tilt angle of approximately 7 degrees is preferable for these ion implantations, but it is not limited to this. Further, the ion implantations may be performed separately at the implantation conditions with different tilt angles if needed, and an implantation for threshold control of a transistor may also be added.

Next, as shown in FIG. 8D, the n-type diffusion layers 105a, 105b, and 105c are formed in a part of the p-type semiconductor substrate 101 by combining a resist pattern formation according to a normal lithography, and an ion implantation. Exactly the same processes as those of the first embodiment shown in FIG. 3A through FIG. 3B my be used for the processes after this.

According to this embodiment, in the process shown in FIG. 8C, an amount of p-type impurity included in a portion which forms the n-type well region 104 is almost the same as the high impurity concentration (1×10¹⁴ to 5×10¹⁵ cm⁻³) of the substrate and is very low, so that in order to form the n-type well region 104, what is necessary is to introduce only the n-type impurities exceeding this amount, thereby making it possible to reduce the amount of ion implantation for forming the n-type well region 104. Accordingly, the high impurity concentration of the n-type well region 104 can also be reduced, so that withstand voltages of the p-type well region 103 and the n-type well region 104 can be improved. In addition, under a state where the same voltage is applied a leakage current flowing between the p-type well region 103 and the n-type well region 104 can be reduced.

### Fourth Embodiment

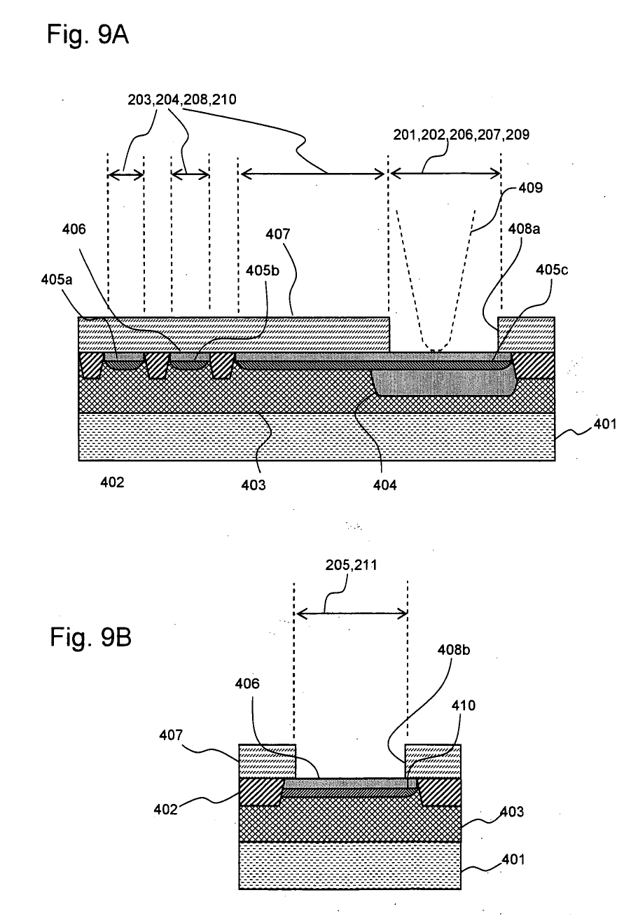

A semiconductor device according to a fourth embodiment of the present invention and a manufacturing method thereof will be explained based on FIG. 9 through FIG. 11.

A plan view of the semiconductor device according to this embodiment is the same as that of the semiconductor device according to the first embodiment (FIG. 1A or FIG. 1B).

FIG. 9A and FIG. 9B are a sectional view in C-C and a sectional view in D-D in FIG. 1A, respectively, corresponding to the plan view of the semiconductor device according to this embodiment.

FIG. 9A is a sectional view of a first or a second electrode for probe and a first or a second evaluation pattern.

The first or the second evaluation pattern includes n-type diffusion layers 405a, 405b and 405c (first diffusion layer region) which are formed adjacent to a device isolation oxide film 402 (device isolation region) formed in a main surface of a p-type semiconductor substrate 401, and a silicide layer 406 formed on the n-type diffusion layers 405a, 405b, and 405c. In addition, the first or the second electrode for probe includes the silicide layer 406 which is formed on the n-type diffusion layer 405c formed adjacent to the device isolation oxide film 402, and an opening for probe 408a which is formed into an interlayer dielectric 407 on the silicide layer 406. A p-type well region 403 (semiconductor region) is formed under the n-type diffusion layers 405a, 405b, and 405c so as to contact to the n-type diffusion layers 405a, 405b, and 405c. Additionally, an n-type well region 404 (second diffusion layer region) is selectively formed under the n-type diffusion layer 405c formed under the first or the second electrode for probe so as to contact to the n-type the diffusion layer 405c and the p-type well region 403.

Incidentally, the silicide layer 406 exposed to the opening for probe 408a is used as the electrodes 201, and 202 in FIG. 1A here. In addition, the silicide layer 406, then-type diffusion layers 405a and 405b, and a part of the n-type diffusion layer 405c, which are isolated by the device isolation oxide film 402 and formed under the interlayer dielectric 407, are used as the first or the second evaluation pattern 203, 204 in FIG. 1A.

Incidentally, when n-type diffusion layer 405c and the deep n-type diffusion layer 404 are considered as one combined n-type diffusion layer, it can be said that a film thickness of the combined n-type diffusion layer formed under the first or the second electrode region for probe is thicker than that of the n-type diffusion layers 405a and 405b formed under the first or the second evaluation pattern area.

FIG. 9B is a sectional view of a third electrode for probe. The third electrode for probe includes the silicide layer 406 which is formed on a p-type diffusion layer 410 formed adjacent to the device isolation oxide film 402 (device isolation region) formed in the main surface of the p-type semiconductor substrate 401, and an opening for probe 408b which is formed into the interlayer dielectric 407 on the silicide layer 406. Incidentally, the silicide layer 406 exposed to the opening for probe 408b is used as the electrode 205 in FIG. 1A here.

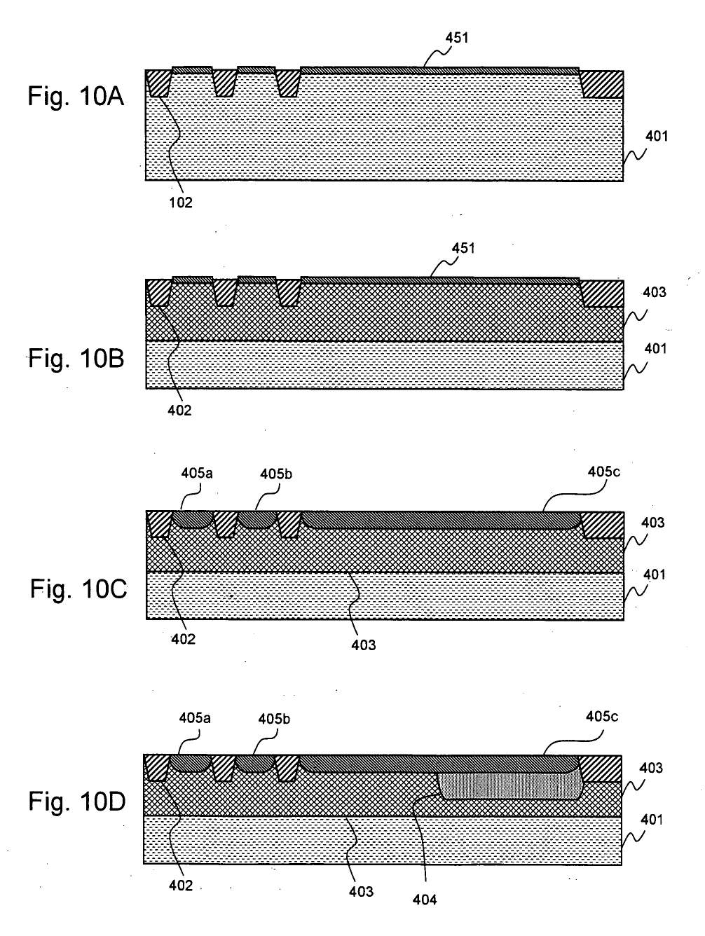

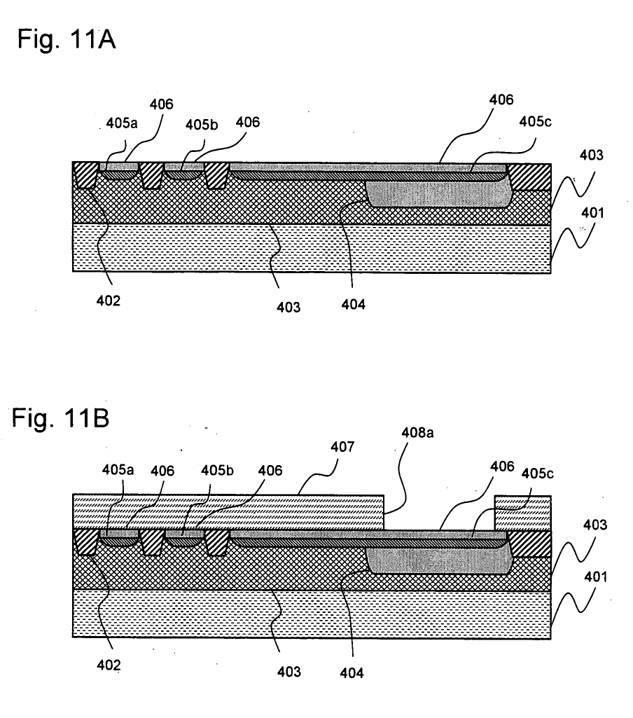

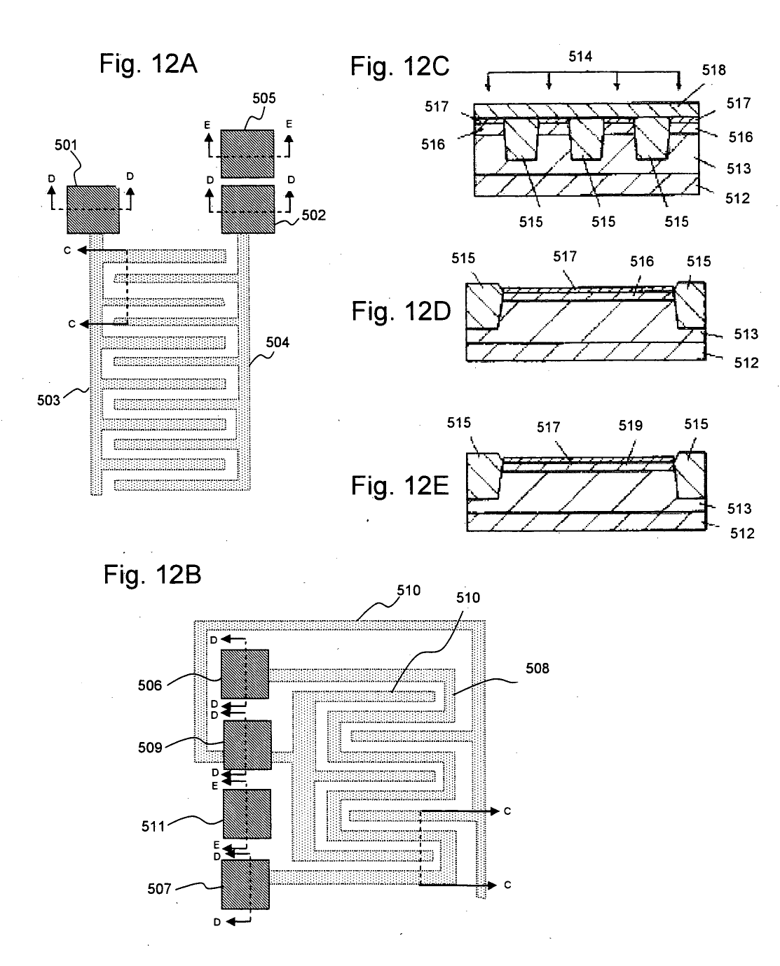

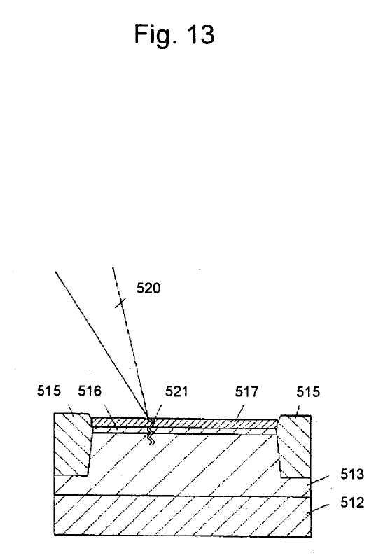

Next, the manufacture method of the semiconductor device according to this embodiment will be explained using FIG. 10A through FIG. 10D, FIG. 11A, and FIG. 11B.

FIG. 10A through FIG. 10D, FIG. 11A, and FIG. 11B are sectional views of the main processes for explaining the manufacturing process of the first or the second electrode for probe and the first or the second evaluation pattern in the evaluation element which composes the semiconductor device according to this embodiment.

First, as shown in FIG. 10A, the device isolation oxide film 402 is formed in the main surface of the p-type semiconductor substrate 401 using the STI (Shallow Trench Isolation) method or the like. A silicon oxide 451 is formed in a portion where the device isolation oxide film 402 is not formed on the main surface of the p-type semiconductor substrate 401.

Next, as shown in FIG. 10B, boron ions at a dose of 1×10¹³ are implanted into a whole surface of the p-type semiconductor substrate 401 at an acceleration energy of 250 keV to form the p-type well region 403. In addition to this, boron ions at a dose of 1×10¹³ are implanted at an acceleration energy of 100 keV as an N-channel stopper in a manner similar to that. These implantation energies and doses are not limited those described above, and in order to form the p-type well region 403 with a desired concentration and depth, they can generally be selected in a range of implantation energy of 100 to 500 keV and of dose of 1×10¹² to 1×10¹⁴. In addition, the tilt angle of approximately 7 degrees is preferable for these ion implantations, but it is not limited to this. Further, the ion implantations may be performed separately at the implantation conditions with different tilt angles if needed, and an implantation for threshold control of a transistor may also be added.

Next, as shown in FIG. 10C, the n-type diffusions layers 405a, 405b, and 405c are formed in a part of the p-type semiconductor substrate 401 by combining a resist pattern formation according to a normal lithography, and an ion implantation. The n-type diffusions layers 405a, 405b, and 405c are formed self-alignedly relative to the device isolation oxide film 402. As a condition for the ion implantation, As ions at a dose of 4×10¹⁵ are implanted at an acceleration energy of 50 keV. In addition to this, phosphorus ions at a dose of approximately 4×10¹³may be implanted at an acceleration energy of 40 keV. These implantation energies are not limited to those described above, but those may be selected freely to form the n-type diffusion layers 405a, 405b, and 405c with a desired depth. Meanwhile, in order to suppress a contact resistance, an implantation dose of approximately 1×10¹⁵ to 8×10¹⁵ in total may preferably be implanted by combining As ions and P ions. In addition, the tilt angle of approximately 7 degrees is preferable for these ion implantations, but it is not limited to this. Further, the ion implantations may be performed separately at the implantation conditions with different twist angles if needed. In addition, although it is not shown, in order to form the third electrode for probe in FIG. 9B, As ions at a dose of 4×10¹⁵ are implanted at an acceleration energy of 15 keV so as to form the p-type the diffusion layer 410 in a part of the p-type semiconductor substrate 401. In addition to this, boron ions at a dose of approximately 4×10¹³ may be implanted at an acceleration energy of 40 keV. These implantation energies and doses are not limited to the conditions described above, similar to the As or phosphorus ion implantation in forming the n-type diffusion layers 405a, 405b, and 405c, and those may be selected freely to form the p-type diffusion layer 410 with a desired depth and concentration.

Next, as shown in FIG. 10D, the deep n-type diffusion layer 404 is formed in a part of the p-type semiconductor substrate 401 by combining a resist pattern formation according to a normal lithography, and an ion implantation. The deep n-type diffusion layer 404 is provided only under the first and the second electrodes for prove. The electrode regions correspond to the electrodes 201 and 202 in FIG. 1A. The deep n-type diffusion layer 404 is formed self-alignedly relative to the device isolation oxide film 402. As a condition for the ion implantation, phosphorus ions at a dose of approximately 1×10¹⁵ are implanted at an acceleration energy of 50 to 100 keV. These implantation energies are not limited to those described above, but may be selected freely to form the deep n-type diffusion layer 404 with a desired depth. Meanwhile, from a viewpoint of a withstand voltage or a leakage current, an implantation dose amount between approximately 5×10¹⁴ to 8×10¹⁵ is preferable for the implantation.

Next, as shown in FIG. 11A, a self aligned silicide process using Co, Ti, nickel, or the like is performed, and the silicide layer 406 is formed on the n-type diffusions layers 405a, 405b, and 405c and the p-type the diffusion layer 410 in FIG. 9B. When forming, for example a Co silicide, a Co metal thin film with a thickness of approximately 10 nm is formed, and then a TiN thin film is continuously formed in a thickness of 10 to 20 nm, unreacted Co is removed with an acid after a heat treatment at 400 to 500 degrees C., and a heat treatment at 700 to 800 degrees C. is further performed, so that the silicide layer 406 with a thickness of approximately 30 to 80 nm can be formed.

Next, as shown in FIG. 11B, the interlayer dielectric 407 is formed on the p-type semiconductor substrate 401 using a plasma CVD method or the like. As the interlayer dielectric 407, a silicon oxide, a SiOF film obtained by introducing fluorine into a silicon oxide, a silicon nitride, an organic thin film, such as polyimide or the like may be used. Next, a part of the interlayer dielectric 407 is etched by combining a resist pattern formation according to a normal lithography and a dry etching, and then the opening for probe 408a is formed in a required region, so that the formation of the semiconductor device is finally completed. The silicide layer 406 exposed to the opening for probe 408a corresponds to the electrode 201 or 202 in FIG. 1A, and the silicide layer 406 exposed to the opening for probe 408b corresponds to the electrode 205 in FIG. 1A. When the polyimide or the like is used as the interlayer dielectric 407, the openings for probe 408a and 408b can be formed only by a coat, development, and cure.

In order to evaluate the semiconductor device according to this embodiment, a probe needle 409 is contacted onto the silicide layer 406 exposed to a portion where the opening for probe 408a is formed as shown in FIG. 9A. At this time, as the probe needle 409, it is desirable to use a material softer than a normal material. Meanwhile, the valuation method of this embodiment is the same as that explained in the first embodiment.

According to the method of manufacturing the semiconductor device of this embodiment, in the process shown in FIG. 10D, the deep n-type diffusion layer 404 can be formed under the electrode 201 and the electrode 202 without using an implantation with a high acceleration energy of 200 keV or more.

Further, according to the semiconductor device of this embodiment, since a depth of the deep n-type diffusion layer 404 is deeper than that of the n-type diffusions layers of 405a, 405b, and 405c by two times or more, when using a material softer than a normal material as the probe needle 409, the damage does not reach this depth, so that the junction leakage current is not produced. Therefore, that makes it possible to perform the electrical fault detection correctly. When using this embodiment, since it is not necessary to add the implantation with a high acceleration energy as described above, a burden of the implanting machine for high acceleration energy may not be increased.

Incidentally, the constitution in FIG. 1B may be employed instead of that in FIG. 1A.

In the first through the fourth embodiments, as the semiconductor which composes the semiconductor substrates 101, 301, and 401, silicon, germanium, those compounds, III-V group semiconductors, such as GaAs, GaN, and GaP, and II-VI group semiconductors, such as ZnSe, or the like may be used.

What is claimed is:

1. A semiconductor device, comprising an element for evaluation,
wherein said element for evaluation comprises
a device isolation region,
a first diffusion layer region formed adjacent to said device isolation region,
an electrode for probe formed to be electrically connected to said first diffusion layer region,
a semiconductor region which is formed under said first diffusion layer region so as to contact to said first diffusion layer region, and has a conductivity type different from that of said first diffusion layer region, and
an evaluation pattern which is formed to be electrically connected to said electrode for probe, and includes at least a part of said first diffusion layer region, and
wherein a second diffusion layer region, which has the same conductivity type as that of said first diffusion layer region, is selectively formed under said first diffusion layer region formed under said electrode for probe so as to contact to said first diffusion layer region and said semiconductor region.

2. The semiconductor device according to claim 1, wherein a high impurity concentration of said second diffusion layer region is higher than that of said semiconductor region.

3. A semiconductor device, comprising an element for evaluation,
wherein said element for evaluation comprises
a device isolation region,
a diffusion layer region formed adjacent to said device isolation region,
an electrode for probe formed to be electrically connected to said diffusion layer region,
a semiconductor region which is formed under said diffusion layer region so as to contact to said diffusion layer region, and has a conductivity type different from that of said diffusion layer region, and
an evaluation pattern which is formed to be electrically connected to said electrode for probe, and includes at least a part of said diffusion layer region, and
wherein a layer thickness of said diffusion layer region which is formed under said electrode for probe is formed to be thicker than that of said diffusion layer region which composes said evaluation pattern.

4. The semiconductor device according to claim 1, wherein
said element for evaluation is formed on a semiconductor substrate,
a conductivity type of said semiconductor region and a conductivity type of said semiconductor substrate are different form each other, and
at least a part of said semiconductor region is formed so as to surround the sides and the bottom of said diffusion layer region or said second diffusion layer region formed under said electrode for probe.

5. The semiconductor device according to claim 2, wherein
said element for evaluation is formed on a semiconductor substrate,
a conductivity type of said semiconductor region and a conductivity type of said semiconductor substrate are different form each other, and
at least a part of said semiconductor region is formed so as to surround the sides and the bottom of said diffusion layer region or said second diffusion layer region formed under said electrode for probe.

6. The semiconductor device according to claim 3, wherein
said element for evaluation is formed on a semiconductor substrate,
a conductivity type of said semiconductor region and a conductivity type of said semiconductor substrate are different form each other, and
at least a part of said semiconductor region is formed so as to surround the sides and the bottom of said diffusion layer region or said second diffusion layer region formed under said electrode for probe.

7. The semiconductor device according to claim 1, wherein a compound which is composed of a main constitution element of said semiconductor region and a metallic element is formed on said diffusion layer region or said first diffusion layer region.

8. The semiconductor device according to claim 2, wherein a compound which is composed of a main constitution element of said semiconductor region and a metallic element is formed on said diffusion layer region or said first diffusion layer region.

9. The semiconductor device according to claim 3, wherein a compound which is composed of a main constitution element of said semiconductor region and a metallic element is formed on said diffusion layer region or said first diffusion layer region.

10. The semiconductor device according to claim 4, wherein a compound which is composed of a main constitution element of said semiconductor region and a metallic element is formed on said diffusion layer region or said first diffusion layer region.

11. The semiconductor device according to claim 5, wherein a compound which is composed of a main constitution element of said semiconductor region and a metallic element is formed on said diffusion layer region or said first diffusion layer region.

12. The semiconductor device according to claim 6, wherein a compound which is composed of a main constitution element of said semiconductor region and a metallic element is formed on said diffusion layer region or said first diffusion layer region.

13. The semiconductor device according to claim 7, wherein
the main constitution element of said semiconductor region is silicon, and
said metallic element is selected from at least one of titanium, cobalt, nickel, tungsten, and molybdenum.

14. A method of manufacturing a semiconductor device, comprising the steps of:
forming a device isolation region in a semiconductor substrate;
forming a semiconductor region which has the same conductivity type as that of said semiconductor substrate in at least a part of said semiconductor substrates;
forming a first diffusion layer region which has a conductivity type different from that of said semiconductor region in at least a part of region in said semiconductor substrate so as to contact to said device isolation region;
after or before forming said first diffusion layer region, forming a second diffusion layer region which has a conductivity type different from that of said semiconductor substrate in at least a part of region in said semiconductor substrate so as to contact to said semiconductor region;
forming a silicide region on said first diffusion layer region; and
forming an electrode for probe in at least a part of region of said silicide region,
wherein said second diffusion layer region is selectively formed under said first diffusion layer region formed under said electrode for probe so as to contact to said first diffusion layer region.

15. A method of manufacturing a semiconductor device, comprising the steps of:
forming a device isolation region in a semiconductor substrate;
forming a semiconductor region which has a conductivity type different from that of said semiconductor substrate in at least a part of said semiconductor substrates;
forming a first diffusion layer region which has the same conductivity type as that of said semiconductor substrate in at least a part of region in said semiconductor substrate so as to contact to said device isolation region;
after or before forming said first diffusion layer region, forming a second diffusion layer region which has a conductivity type different from that of said semiconductor region in at least a part of region in said semiconductor substrates so as to contact said semiconductor region and so as for its bottom to be located upper than the bottom of said semiconductor region;
forming a silicide region on said first diffusion layer region; and
forming an electrode for probe in at least a part of region of said silicide region,
wherein said second diffusion layer region is selectively formed under said first diffusion layer region formed under said electrode for probe so as to contact to said first diffusion layer region.

16. The method of manufacturing the semiconductor device according to claim 14, wherein the process for forming said semiconductor region includes a process for forming a mask in a region where said second diffusion layer region is formed.

17. The method of manufacturing the semiconductor device according to claim 15, wherein the process for forming said semiconductor region includes a process for forming a mask in a region where said second diffusion layer region is formed.
